(19) United States
(12) Patent Application Publication
(10) Pub. No.: US 2012/0069681 A1
(43) Pub. Date: Mar. 22, 2012

(54) SEMICONDUCTOR STORAGE DEVICE

(76) Inventor: Kohei OIKAWA, Kawasaki-shi (JP)

(21) Appl. No.: 13/052,167

(22) Filed: Mar. 21, 2011

(30) Foreign Application Priority Data
Sep. 22, 2010 (JP) 2010-212719

(51) Int. Cl. G11C 16/10

(52) U.S. Cl. 365/185.24; 365/185.18

(57) ABSTRACT

According to one embodiment, a semiconductor storage device includes a cell array, a controller, and a voltage generator. The cell array includes cells. Each of the cells holds data “0” or “1”. The controller counts the number of times N of sequentially writing the data into the cells. The controller transfers a write voltage and a read voltage. The write voltage and the read voltage are variable according to the number of times N. The voltage generator generates the write voltage and the read voltage. When the N-th (≧2) write request is issued to the cell, the controller causes the voltage generator to generate the read voltage corresponding to an (N−1)th time. The controller causes the voltage generator to generate the write voltage which changes a threshold voltage of the cell. When the cell has reached a prescribed value, the controller erases the data held in the cell.

### CROSS-REFERENCE TO RELATED APPLICATIONS

This application is based upon and claims the benefit of priority from Japanese Patent Application No. 2010-212719, filed Sep. 22, 2010; the entire contents of which are incorporated herein by reference.

### FIELD

Embodiments described herein relate generally to a semiconductor storage device such as a NAND-type flash memory.

### BACKGROUND

A NAND-type flash memory uses a memory cell having a floating gate (FG). In writing data, a charge is accumulated in the floating gate of the memory cell to change a threshold voltage and thereby hold the data. In reading data, information corresponding to the threshold voltage, that is, the amount of the charge accumulated in the floating gate is read.

The memory cell may not only hold one-bit (“0” or “1”) data but may also hold multi-valued (e.g., two bits (“11”, “10”, “01” or “00”)) data. For two bits, one of four threshold voltages is set in the memory cell. Higher accuracy is required to set the threshold voltage than to store one bit, but the amount of a threshold change in writing is not much different from that in writing one bit. Thus, in writing in a memory cell, the threshold of a neighboring memory cell may be shifted and data held therein may be changed due to capacitive coupling between memory cells, that is, there is a strong possibility of program disturb.

Furthermore, data is not finely read when, for example, the characteristics of a memory cell capable of holding four-value data deteriorate and thresholds are widely distributed. In such a case, a change from a four-value mode to a two-value mode has to be made.

Moreover, when data is once held in a memory cell by the rise of its threshold voltage and then additional new data is written in the memory cell, the threshold voltage has to be dropped by erasing. The number of times of erasing is limited to, for example, about ten thousand. Increasing the number of times of erasing decreases the speed of writing and accelerates the declining of the memory cell.

### BRIEF DESCRIPTION OF THE DRAWINGS

FIG. 1 shows a configuration example of a NAND-type flash memory according to a first embodiment;

FIG. 2 is a conceptual diagram of a threshold distribution of a memory cell according to the first embodiment;

FIG. 3 is a conceptual diagram of held data in the memory cell according to the first embodiment;

FIG. 4 is a block diagram of a voltage generator according to the first embodiment;

FIG. 5 is a flowchart showing the operation of a controller according to the first embodiment;

FIG. 6 is a time chart showing write operation in the NAND-type flash memory according to the first embodiment;

FIG. 7 is a conceptual diagram showing data held in the memory cell corresponding to a read voltage according to the first embodiment;

FIG. 8 is a flowchart showing the operation of the controller according to the first embodiment;

FIG. 9 is a flowchart showing the operation of the controller according to the first embodiment;

FIG. 10 is a conceptual diagram of a threshold distribution of memory cells according to a modification of the first embodiment;

FIG. 11 is a conceptual diagram of data held in the memory cell corresponding to a read voltage according to the modification of the first embodiment;

FIG. 12 shows a configuration example of a memory system according to a second embodiment;

FIG. 13 shows a configuration example of a work memory according to the second embodiment;

FIG. 14 shows a configuration example of a memory cell array according to a third embodiment;

FIG. 15 shows a detailed configuration example of the memory cell array according to the third embodiment;

FIG. 16 is a perspective view of the memory cell arrays according to the third embodiment;

FIG. 17 is a circuit diagram of the memory cell array according to the third embodiment;

FIG. 18 is a distribution map of resistance to which the memory cell array according to the third embodiment may change to;

FIG. 19 is a conceptual diagram of data held in the memory cell according to the third embodiment; and

FIG. 20 is a conceptual diagram of write voltages according to the third embodiment.

### DETAILED DESCRIPTION

Hereinafter, an embodiment is described with reference to the drawings. In this description, a common reference number is assigned to a common part throughout the drawings.

In general, according to one embodiment, a semiconductor storage device includes a memory cell array, a controller, and a voltage generator. The memory cell array includes memory cells. Each of the memory cells is capable of holding data “0” or “1” according to a read level. The memory cells are arranged along row and column directions. The controller counts the number of times N (N: an integral number equal to or more than 0) of sequentially writing the data into the memory cell. The controller transfers a write voltage and a read voltage to the memory cell. The write voltage and the read voltage are variable according to the number of times N. The voltage generator generates the write voltage and uses this write voltage to write at least “1” bit data into the memory cell. The voltage generator generates the read voltage and reads the at least “1” bit data from the memory cell. When the N-th (≧2) write request is issued to the memory cell, the controller causes the voltage generator to generate the read voltage corresponding to an (N−1)th time, and uses this read voltage to read the “1” bit data from the memory cell. According to the data corresponding to the write request, the controller causes the voltage generator to generate the write voltage which changes a threshold voltage of the memory cell to higher threshold voltage than a threshold voltage of the memory cell at which the data is read in the (N−1)th reading. When the N has reached a prescribed value, the controller erases the data held in the memory cell.

According to the data corresponding to the write request, the controller causes the voltage generator to generate the write voltage which changes to a threshold voltage higher than a threshold voltage of the memory cell at which the data is read in the (N−1)th reading. When the N-th (≧2) write request to the memory cell has reached a prescribed value, the controller erases the data held in the memory cell.

### First Embodiment

According to this embodiment, in writing new data into a memory cell, the new data is sequentially written without erasing held data. That is, the threshold voltage of the memory cell is raised every writing. In reading, a read level corresponding to the number of times of writing is used to judge whether the threshold voltage of the memory cell is lower or higher than the read level, thereby reading one-bit (“0” or “1”) data. Further, when the number of times of writing reaches a prescribed value, the data is erased. That is, the data is not erased until the number of times of writing into the memory cell reaches the prescribed value, and data is written into the same memory cell more than one time. Moreover, the number of times of writing in the memory cell is managed by block units described later in order to suppress program disturb.

<Overall Configuration Example>

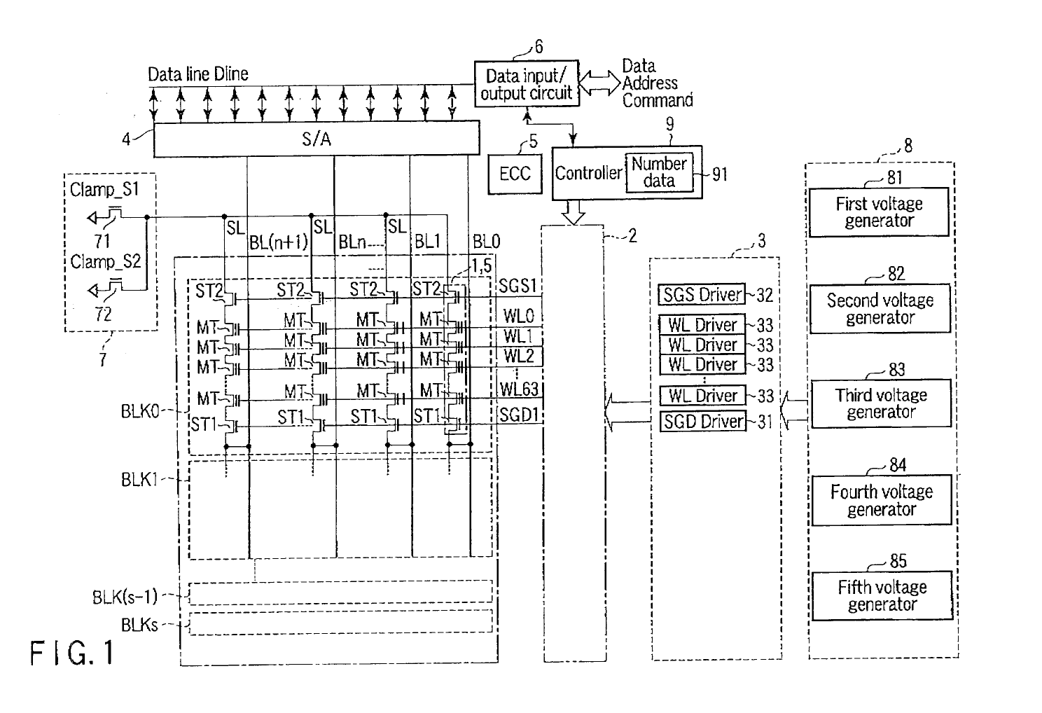

A configuration example of a semiconductor storage device according to this embodiment is described with reference to FIG. 1. FIG. 1 is a block diagram showing by way of example the semiconductor storage device according to this embodiment. As shown in FIG. 1, a NAND-type flash memory includes a memory cell array 1, a row decoder 2, a driver circuit 3, a sense amplifier 4, an ECC circuit 5, a data input/output circuit 6, a source line SL driver 7, a voltage generator 8, and a controller 9.

The memory cell array 1 includes blocks BLK0 to BLKs including nonvolatile memory cell transistors MT (s is a natural number). Each of the blocks BLK0 to BLKs includes NAND strings 15 in which the nonvolatile memory cell transistors MT are connected in series. Each of the NAND strings 15 includes, for example, 64 memory cell transistors MT, and select transistors ST1 and ST2.

The memory cell transistors MT are capable of holding data of two or more values. While two-value data at different levels are held in this embodiment described, data is not limited in value and may be four-value data or eight-value data.

The structure of the memory cell transistor MT is an FG type including a floating gate (conductive layer) which is formed on a p-type semiconductor substrate so that a gate insulating film intervenes in between, and a control gate which is formed on the floating gate so that an inter-gate insulating film intervenes in between. The memory cell transistor MT may otherwise be a MONOS type. The MONOS type is a structure comprising a charge accumulation layer (e.g., an insulating film) formed on a semiconductor substrate so that a gate insulating film intervenes in between, an insulating film (hereinafter referred to as a block layer) formed on the charge accumulation layer and having a higher dielectric constant than the charge accumulation layer, and a control gate further formed on the block layer.

The control gate of the memory cell transistor MT functions as a word line. The drain thereof is electrically connected to a bit line, and the source thereof is electrically connected to a source line. The memory cell transistor MT is an n-channel MOS transistor. The number of the memory cell transistors MT is not exclusively 64, and may be, for example, 128 or 256.

The adjacent memory cell transistors MT share the source and the drain. The memory cell transistors MT are arranged between the select transistors ST1 and ST2 so that the current paths thereof are connected in series. The drain region at one end of the memory cell transistor MT connected in series is connected to the source region of the select transistor ST1. The source region at the other end is connected to the drain region of the select transistor ST2.

The control gates of the memory cell transistors MT in the same row are connected to one common word line out of word lines WL0 to WL63. The gate electrodes of the select transistors ST1 and ST2 of the memory cell transistors MT in the same row are connected to common select gate lines SGD1 and SGS1, respectively. For the simplification of explanation, the word lines WL0 to WL63 may be hereinafter referred to simply as a word line WL when not distinguished from one another. Moreover, the drains of the select transistors ST1 in the same column in the memory cell array 1 are connected to one common bit line out of bit lines BL0 to BLn. The bit lines BL0 to BLn will be hereinafter referred to collectively as a bit line BL when not distinguished from one another (n is a natural number). The sources of the select transistors ST2 are connected to a common source line SL.

Furthermore, data is collectively written into the memory cell transistors MT connected to the same word line WL, and the unit of these memory cell transistors MT is referred to as a page. Data is collectively erased in the memory cell transistors MT per block BLK.

The row decoder 2 is described. In the writing, reading and erasing of data, the row decoder 2 decodes a block address provided from the controller 9, and selects a block BLK accordingly. Thus, the row decoder 2 selects the row direction of the memory cell array 1 corresponding to the selected block BLK. That is, in accordance with a control signal provided from the controller 9, the row decoder 2 applies voltages provided from the driver circuit 3 to the select gate lines SGD1 and SGS1 and the word lines WL0 to WL63, respectively.

The driver circuit 3 includes select gate line drivers 31 and 32 respectively provided for the select gate lines SGD1 and SGS1, and word line drivers 33 respectively provided for the word lines WL. In this embodiment, the word line drivers 33 and the select gate line drivers 31 and 32 corresponding to the block BLK0 are only shown. However, the word line drivers 33 and the select gate line drivers 31 and 32 are actually connected to, for example, the common 64 word lines WL and select gate lines SGD1 and SGS1 that are provided in the blocks BLK0 to BLKs.

A block BLK is selected according to the result of decoding a page address provided from the controller 9. The word line driver 33 transfers a required voltage provided from the voltage generator 8 via the selected word line WL, to the control gate of the memory cell transistor MT provided in the selected block BLK. The select gate line driver 31 also transfers a required voltage to the gate of the select transistor ST1 via the select gate line SGD1 corresponding to the selected block BLK. At the same time, the select gate line driver 31 transfers a signal sgd to the gate of the select transistor ST1. Specifically, in the writing, reading, and erasing of data and in the verification of data, the select gate line driver 31 transfers, for example, the signal sgd to the gate of the select transistor ST1 via the select gate line SGD1. When at a “L” level, the signal sgd is set to 0 [V]. When at a “H” level, the signal sgd is set to a voltage VDD (e.g., 1.8 [V]).

Furthermore, the select gate line driver 32 transfers, to the gate of the select transistor ST2 via the select gate line SGS1 corresponding to the selected block BLK, a voltage required via the select gate line SGS1 in the writing and reading of data and in the verification of data. At the same time, the select gate line driver 32 transfers a signal sgs to the gate of the select transistor ST2. When at a “L” level, the signal sgs is set to 0 [V]. When at an “H” level, the signal sgs is set to the voltage VDD.

Next, the sense amplifier 4 is described. The sense amplifier 4 senses and amplifies data read from the bit line BL (bit line BL targeted for reading) connected to the memory cell transistor MT targeted for reading in the reading of the data.

Specifically, after the bit line BL targeted for reading is pre-charged with a predetermined voltage (e.g., the voltage VDD), the sense amplifier 4 discharges the bit line BL through the NAND string 15 selected by the row decoder 2, and senses the discharge state of this bit line BL. That is, the sense amplifier 4 amplifies the voltage of the bit line BL and thus senses the data in the memory cell transistor MT. The read data is then transferred to the data input/output circuit 6 via a data line Dline. In addition, the bit lines BL which are not targeted for reading in this case are fixed to the voltage VDD.

In the writing of data, the sense amplifier 4 transfers write data to the bit line BL targeted for writing. Specifically, a predetermined voltage (e.g., the voltage VDD) is transferred to the bit line BL in the writing of data “0”, and 0 V, for example, is transferred to the bit line BL in the writing of data “1”. In addition, the bit lines BL which are not targeted for reading in this case are fixed to the voltage VDD.

The ECC circuit 5 corrects errors in data, and also count the number of error bits. The data input/output circuit 6 outputs, to the controller 9, an address and a command supplied from a host via an unshown I/O terminal. The data input/output circuit 6 also outputs write data to the sense amplifier 4 via the data line Dline and an unshown data buffer BF. Moreover, when outputting data to the host, the data input/output circuit 6 receives the data amplified by the sense amplifier 4 via the data line Dline and outputs the data to the host via the I/O terminal according to the control of the controller 9.

The source line SL driver 7 includes MOS transistors 71 and 72. One end of the current path of the MOS transistor 71 is connected to the source line SL, the other end thereof is grounded, and a signal Clamp_S1 is provided to the gate thereof. One end of the current path of the MOS transistor 72 is connected to one end of the current path of the MOS transistor 71, the other end thereof is supplied with the voltage VDD, and a signal Clamp_S2 is provided to the gate thereof.

When the MOS transistor 71 is turned on, the potential of the source line SL is set to 0 [V]. When the MOS transistor 72 is switched on, the potential of the source line SL is set to the voltage VDD. The signals Clamp_S1, S2 provided to the gates of the MOS transistors 71 and 72 are controlled by the controller 9. The MOS transistor 72 is switched on when erase verify is performed. That is, the voltage VDD is transferred to the bit line BL from the source line SL by switching on the MOS transistor 72 during the erase verify.

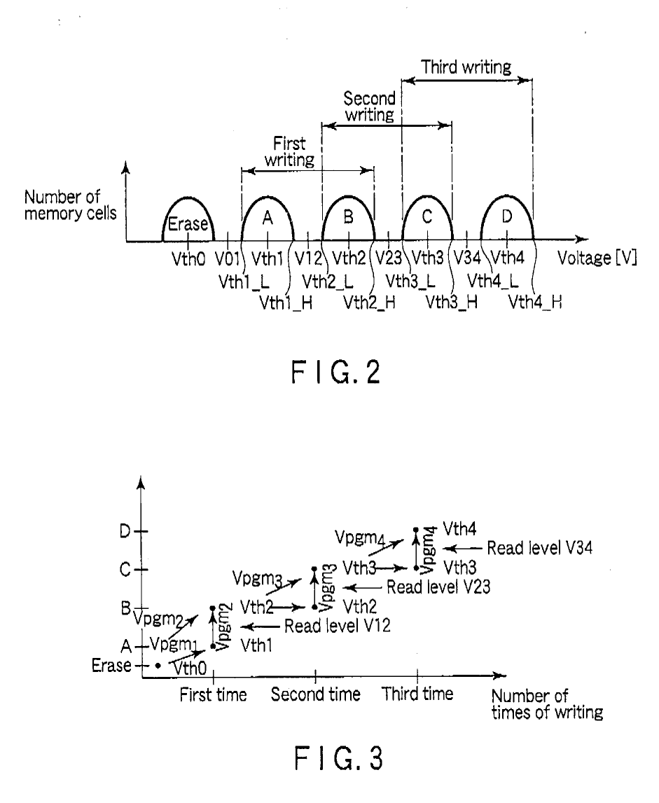

The threshold voltage held by the memory cell transistor MT is described with reference to FIG. 2. FIG. 2 is a graph in which the horizontal axis indicates a threshold distribution and the vertical axis indicates the number of the memory cell transistors MT.

As shown, each of the memory cell transistors MT holds, for example, five state distributions according to the amount of a charge accumulated in the floating gate. That is, the memory cell transistor MT may hold five kinds of state distributions in ascending order of a threshold voltage Vth; an “erased” state, an “A” state, a “B” state, a “C” state, and a “D” state.

A threshold voltage Vth0 in the “erased” state in the memory cell transistor MT is Vth0<V01. A threshold voltage Vth1 in the “A” state is V01<Vth1<V12. In the threshold distribution of this “A” state, a lower voltage is Vth1_L, and an upper voltage is Vth1_H.

A threshold voltage Vth2 in the “B” state is V12<Vth2<V23. In the threshold distribution of this “B” state, a lower voltage is Vth2_L, and an upper voltage is Vth2_H.

A threshold voltage Vth3 in the “C” state is V23<Vth3<V34. In the threshold distribution of this “C” state, a lower voltage is Vth3_L, and an upper voltage is Vth3_H.

Moreover, a threshold voltage Vth4 in the “D” state is V34<Vth4. In the threshold distribution of this “D” state, a lower voltage is Vth4_L, and an upper voltage is Vth4_H. Thus, the memory cell transistor MT may hold five kinds of state distributions according to the threshold. The voltage V01, the voltage V12, the voltage V23, and the voltage V34 are read levels. The voltage Vth1_L, the voltage Vth2_L, the voltage Vth3_L, and the voltage Vth4_L, are verify voltages corresponding to the number of times of writing.

The memory cell transistor MT is set at, for example, a negative voltage in the “erased” state, and is set to a positive threshold voltage by writing data and injecting a charge into the floating gate.

As described above, data is overwritten until the number of times of writing into the memory cell transistor MT reaches the prescribed value. That is, as shown in FIG. 2, the threshold distribution of the memory cell transistor MT is changed to the distribution of the “A” state or “B” state from the “erased” state, for example, by the charge injected into the floating gate by first writing. That is, one-bit information is held. The threshold distribution of the memory cell transistor MT is changed to the distribution of the “B” state or “C” state by the charge injected into the floating gate by second writing. The threshold distribution of the memory cell transistor MT is changed to the distribution of the “C” state or “D” state by the charge injected into the floating gate by third writing. In the later-described reading of data, the value of a read voltage is varied according to the number of times of writing. Thus, one-bit data, that is, data “0” or data “1” is read. When the threshold voltage of the memory cell transistor MT is lower than the read voltage, the memory cell transistor MT holds the data “0”. On the other hand, when the threshold voltage of the memory cell transistor MT is higher than the read voltage, the memory cell transistor MT holds the data “1”.

This situation is described with reference to FIG. 3. FIG. 3 is a conceptual diagram showing the state distribution that may be made by the memory cell transistor MT upon every writing and showing that the read voltage corresponding to the number of times of writing is used to judge the data held in the memory cell transistor MT.

As shown in FIG. 3, the horizontal axis indicates the number of times of writing, and the vertical axis indicates the threshold distributions that may be held by the memory cell transistor MT. As described above, in the first data writing, the threshold distribution of the memory cell transistor MT changes to the state distribution of “A” or “B” from the “erased” state by using a write voltage Vpgm1 or a voltage Vpgm2 described later. Here, if the read level is V12 (see FIG. 2), the “A” state is the data “0”, and the “B” state is the data “1”. In the second data writing, the threshold distribution of the memory cell transistor MT changes to the state distribution of “s” or “C” by using a write voltage Vpgm3 described later. Here, if the read level is V23 (see FIG. 2), the “B” state is the data “0”, and the “C” state is the data “1”. That is, even for the same state distribution, the memory cell transistor MT holds different data depending on the number of times of writing.

Moreover, in the third data writing, the threshold distribution of the memory cell transistor MT changes to the state distribution of “C” or “D” by using a write voltage Vpgm4 described later. Here, if the read level is V34 (see FIG. 2), the “C” state is the data “0”, and the “D” state is the data “1”. Thus, the memory cell transistor MT according to this embodiment holds the data “1” or “0” depending on the number of times of writing and the state distribution thereof.

The voltage generator 8 includes a first voltage generator 81, a second voltage generator 82, a third voltage generator 83, a fourth voltage generator 84, and a fifth voltage generator 85.

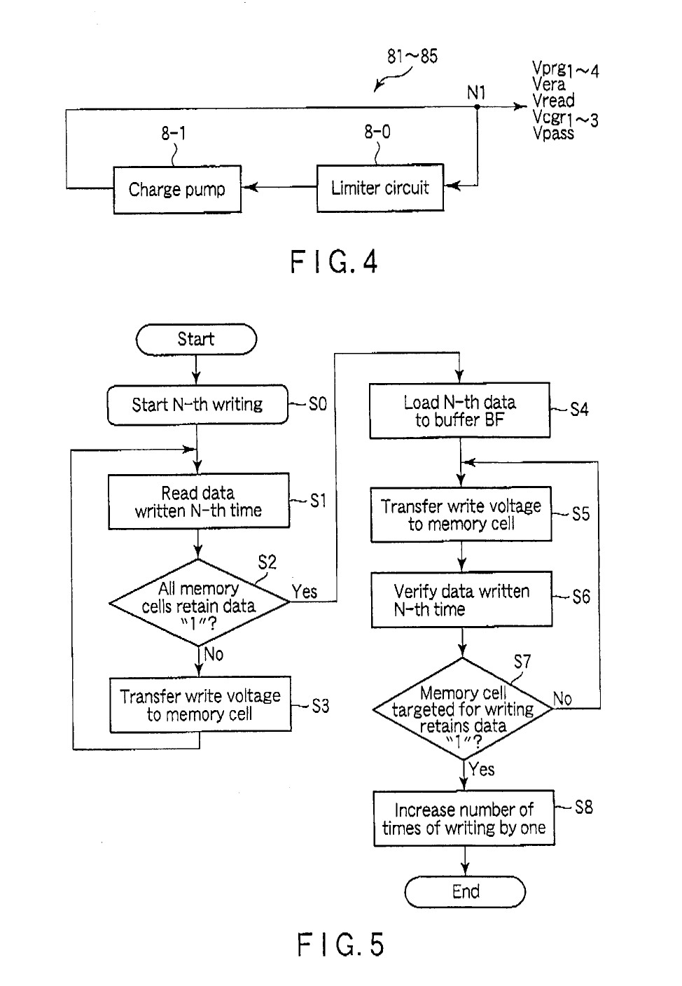

The first voltage generators 81 to the fifth voltage generator 85 are described with reference to FIG. 4.

As shown in FIG. 4, each of the first voltage generator 81 to the fifth voltage generator 85 includes a limiter circuit 8-0 and a charge pump circuit 8-1. The charge pump 8-1 generates, according to the controller 9, voltages required for the operation of, for example, writing, erasing and reading data. Each of the voltages is output from a node N1, and supplied to, for example, the row decoder 2 in the NAND-type flash memory via the driver circuit 3. The limiter circuit 8-0 monitors the potential of the node N1, and at the same time controls the charge pump circuit 8-1 according to the potential of the node N1. That is, if the potential of the node N1 is higher than a predetermined value, the limiter circuit 8-0 stops the pumping of the charge pump circuit 8-1, and drops the potential of the node N1.

On the other hand, if the potential of the node N1 is lower than the predetermined value, the limiter circuit 8-0 allows the charge pump circuit 8-1 to pump, and raises the potential of the node N1.

Next, the voltages generated by the first voltage generator 81 to the fifth voltage generator 85 are described. The first voltage generator 81 generates the voltages Vpgm1 to Vpgm4 in the writing of data (the voltages Vpgm1 to Vpgm4 may be referred to as write voltages Vpgm1 to Vpgm4). The generated voltages Vpgm1 to Vpgm4 are transferred to the selected word line WL, and applied to the control gate of the memory cell transistor MT. The voltages Vpgm1 to Vpgm4 are such degrees of voltages that a charge in a channel formed immediately under the memory cell transistor MT is injected into the floating gate and the threshold of the memory cell transistor MT changes to another level.

Here, the voltages Vpgm1 to Vpgm4 satisfy a relation of Vpgm1<Vpgm2<Vpgm3<Vpgm4. In FIG. 3, the voltage Vpgm1 is a voltage that causes a change from the “erased” state to the “A” state, that is, to the threshold voltage Vth1. The voltage Vpgm2 is a voltage that causes a change from the “erased” state to the “B” state, that is, to the threshold voltage Vth2 and is a voltage that causes a change from the “A” state to the “B” state. The voltage Vpgm3 is a voltage that causes a change from the “B” state to the “C” state, that is, to the threshold voltage Vth3. The voltage Vpgm4 is a voltage that causes a change from the “C” state to the “D” state.

The second voltage generator 82 generates a voltage Vpass, and transfers the voltage Vpass to unselected word lines WL. The voltage Vpass is a voltage that switches on the memory cell transistor MT.

The third voltage generator 83 generates, for example, a voltage Vera of 20 [V], and transfers the voltage to a well region where the memory cell transistor MT is formed. The voltage Vera is a voltage for extracting the charge injected into the floating gate from the floating gate.

The fourth voltage generator 84 generates voltages Vcgr1 to Vcgr3, and transfers the voltages Vcgr1 to Vcgr3 to the selected word line WL. The voltages Vcgr1 to Vcgr3 are read voltages corresponding to data read from the memory cell transistor MT. The voltage Vcgr1 has a value of, for example, voltage Vth1_H<voltage Vcgr1=V12<Vth2_L. The voltage Vcgr2 has a value of, for example, voltage Vth2_H=V23<voltage Vcgr2<Vth3_L. The voltage Vcgr3 has a value of, for example, the voltage Vth3_H< the voltage Vcgr3=V34<Vth4_L.

The fifth voltage generator 85 generates a voltage Vread, and transfers the voltage Vread to unselected word lines WL in the reading of data. The voltage Vread is a voltage which is not dependent on the data held by the memory cell transistor MT and which switches on the memory cell transistor MT.

The controller 9 holds number data 91. The number data 91 holds the number of times in which data is sequentially written into the memory cell transistor MT in each block BLK. The controller 9 manages the number of times of the sequential writing for each block BLK. That is, the number data 91 holds, for example, such information that the number of times of writing into the memory cell transistor MT provided in, for example, the block BLK1 is one, that the number of times of writing into the memory cell transistor MT provided in the block BLK2 is two, and so on.

When the data held by the number data 91 is, for example, 3, the controller 9 resets the value to “0” before the number of times of sequentially writing data into the memory cell transistor MT becomes “4”. That is, when data is already written three times and a new write request is issued by the host, the controller 9 performs an erase operation in the memory cell transistor MT. Accordingly, the threshold voltage changes to, for example, the “erased” state (see FIG. 2), and writing of new write data is prepared.

The controller 9 may set the number of times of writing according to the characteristics of the memory cell transistor MT. That is, the controller 9 may set, according to the characteristics of the memory cell, the number of times data may be overwritten in the memory cell transistor MT. The number of times is set to “3” in the above explanation, but is not exclusively set to this value as long as the characteristics of the memory cell are preferable. For example, the number of times may be “7” or “15”. Alternatively, the number of times may be “5” or “6”. That is, the number of times does not have to be a value which is the power of “2”. This value is represented by L, and the upper limit value at which data may be sequentially written is referred to as a maximum permitted overwriting count LMAX.

When the characteristics of the memory cell transistor MT are preferable and resolution is high, that is, when adjacent threshold distributions are apparently separate from each other, the upper limit value LMAX is increased and set to a high value. That is, more state distributions are added to, for example, the five state distributions of the “erased” state to the “D” state in FIG. 2, and an “E” state and an “F” state having higher voltages than that of the “D” state are set. In contrast, when the resolution is reduced and both ends of the adjacent states (e.g., a potential difference between Vth2_L and Vth1_H in FIG. 2) are close to each other, the LMAX is set, for example, one value higher. Specifically, the threshold distribution ranging from the “A” state to the “D” state that may be held by the memory cell transistor MT as shown in FIG. 2 is set to cover the “A” state, the “B” state, and the “C” state according to the reduction of the characteristics.

The controller 9 may also switch its operation mode to conventional multi-value mode (hereinafter referred to as a mode 1) instead of the mode according to this embodiment (hereinafter referred to as a mode 2).

When the mode of the controller 9 is the mode 1, the memory cell holds four values (“11”, “10”, “01”, and “00”) or eight values (“111”, “110”, “101”, “100”, “011”, “010”, “001”, and “000”). For example, in the mode 1, when 4 bits may not be represented because of, for example, the declining of the characteristics of the memory cell transistor MT, the controller 9 reduces the number of bits so that the held data is represented by 3 bits.

On the contrary, in, for example, the mode 2, the controller 9 changes from the maximum permitted overwriting count LMAX-3 to the maximum permitted overwriting count LMAX-2 according to the degree of the declining of the memory cell transistor MT, and thereby subtracts one state distribution from the previous threshold distribution ranging from the “A” state to the “D” state to leave, for example, the “A” state, the “B” state, and the “C” state.

Furthermore, the controller 9 controls the fourth voltage generator 84 to generate a read voltage corresponding to the above-mentioned number of times of writing. That is, the controller 9 controls the fourth voltage generator 84 to generate the voltage Vcgr1 if the number of times of writing is “1”, to generate the voltage Vcgr2 if the number of times of writing is “2”, and to generate the voltage Vcgr3 if the number of times of writing is “3”,

The controller 9 described above controls the overall operation of the NAND-type flash memory. That is, operation sequences in the operation of writing, reading and “erasing” data are performed according to the address and command provided from the unshown host via the data input/output circuit 6. According to the address and the operation sequence, the controller 9 generates a block selecting signal/a column selecting signal.

The controller 9 manages the number of times of writing for each block BLK as described above. In the overwriting of data, the data held in the memory cell transistor MT by preceding data+writing is read. As a result, if the held data is data “0”, data “1” is held before new data is written. That is, the threshold distribution is changed one level higher.

Specifically, the read voltage is dependent on Vcgr1-V12, and the data held by the memory cell transistor MT as a result of the first writing is the “A” state, that is, data “0”. In this case, the threshold distribution is changed from the “A” state to the “B” state before the second data writing. That is, the controller 9 causes the first voltage generator 81 to apply the voltage Vpgm2 to the memory cell transistor MT.

The controller 9 outputs the above-mentioned block selecting signal to the row decoder 2. The controller 9 also outputs the column selecting signal to the sense amplifier 4. The column selecting signal is a signal for selecting the column direction of the sense amplifier 4.

Furthermore, the controller 9 is provided with a control signal supplied from an unshown memory controller. According to the supplied control signal, the controller 9 determines whether the signal supplied to the data input/output circuit 6 from the host via the unshown I/O terminal is an address or data.

When new data is overwritten, the data held in the memory cell transistor MT by preceding data writing is read, so that if the held data is data “0”, data “1” is held to change the threshold distribution one level higher before the new data is written. However, this embodiment is not limited to this. That is, before the new data is written, the state distribution may be increased to prevent data “1” from being held, and the state distribution may be changed from the threshold voltage corresponding to the preceding held data to the threshold voltage corresponding to the newly written data. Specifically, if the next writing is, for example, the second data writing, the state distribution is changed by the second data writing to the “B” state or the “C” state from the “A” state to which the state distribution is changed in the first writing. Otherwise, the “B” state to which the state distribution is changed in the first writing is maintained or changed to the “C” state by the second data writing. Moreover, the threshold voltage of the memory cell is changed from the “A” state to the “C” state by the voltage Vpgm3, and the threshold voltage of the memory cell is changed from the “B” state to the “D” state by the voltage Vpgm4. That is, even when the threshold voltage is raised two levels, the voltage required to change to a desired threshold voltage described with reference to FIG. 3 may be used.

<Write Operation>

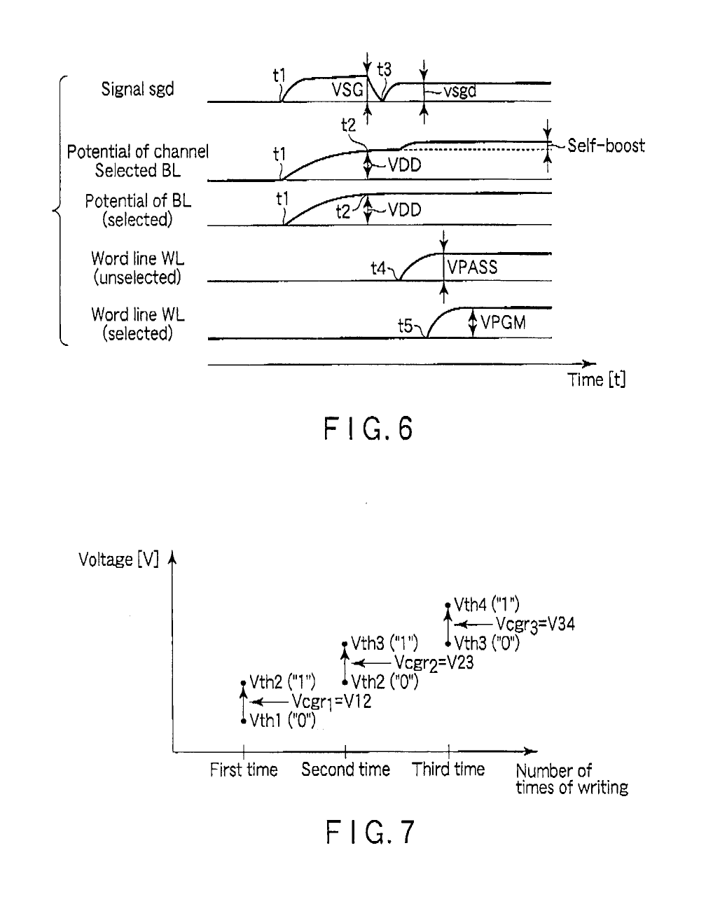

Now, a write operation in the semiconductor storage device according to this embodiment is described with reference to FIG. 5. FIG. 5 is a flowchart showing the write operation. FIG. 6 is a time chart showing the write operation in step S5 (described later) of FIG. 5. Here, the number of times of sequentially writing data is represented by N (N: natural number). In the following explanation, N≧2 is assumed.

If a write command, write data, and the address of the memory cell transistor MT targeted for writing are transferred to the controller 9 from the unshown host via the data input/output circuit 6, the controller 9 refers to the number data 91 to check the number of times of writing in the block BLK where the memory cell transistor MT targeted for writing is provided (step S0).

As a result, if the next write operation is the N-th time, the controller 9 causes the fourth voltage generator 84 to generate a voltage Vcgr(N−1). This voltage Vcgr(N−1) is used to sequentially read data from all of the memory cell transistors MT provided in the block BLK targeted for writing, and whether all of the memory cell transistors MT in the block BLK hold data “1” is judged (S1, S2).

Thus, when there is one or more memory cell transistor MT holding data “0” in the block BLK where the memory cell transistor MT targeted for writing is provided (S2, NO), a write voltage VpgmN is supplied to the memory cell holding the data “0” (S3). This operation is repeated until all of the memory cell transistors MT in the block BLK hold data “1” (S3, S1, S2).

If all of the memory cell transistors MT in the block BLK where the memory cell transistor MT targeted for writing is provided hold data “1” in the step S2 (S2, YES), the controller 9 stores the N-th write data to the unshown data buffer BF from the data input/output circuit 6 via the data line Dline (S4).

Furthermore, the controller 9 transfers a write voltage Vpgm(N+1) to the selected word line WL, and writes, into the memory cell transistor MT, a value (data “0” or “1”) corresponding to the data stored in the data buffer BF (S5). The operation in step S5 is described with reference to FIG. 6.

As described above, FIG. 6 is a time chart showing the operation of writing data “0” in the NAND-type flash memory. As shown, the horizontal axis indicates time, and the vertical axis indicates the signal sgd, the potential of the channel, the potential of the selected bit line BL, the potential of the selected word line WL, and the potential of the unselected word line WL. In addition, the operation of the unselected bit line BL is the same as the writing of the data “0” in the selected bit line BL and is therefore not described below.

In this embodiment, the selected word line WL in the memory cell transistor MT targeted for writing is, for example, the word line WL32. Thus, the voltage Vpass is transferred to the unselected word lines WL0 to 31 and WL33 to 63, and the voltage Vpgm(N+1) is transferred to the selected word line WL32.

First, the potential of the selected word line WL rises from a time t1 by a pre-charge voltage transferred by the sense amplifier 4 at the time t1.

At the same time t1, the signal sgd at the “H” level is also supplied to the gate of the select transistor ST1. That is, the signal sgd rises to, for example, the voltage VDD, so that the select transistor ST1 is turned on. Thus, the potential of the channel of the memory cell transistor MT rises from the time t1.

Furthermore, at a time t2, the potential of the selected bit line BL and the potential of the channel of the selected bit line BL also reach the voltage VDD (are saturated). That is, a current of the bit line BL, at the time t2 is substantially zero.

At a time t3, the signal sgd drops to a zero potential. As a result, the select transistor ST1 is cut off. Further, at a time t4, the voltage Vpass is transferred to the unselected word lines WL0 to 31 and WL33 to 63. Thus, the potential of the bit line BL rises from the voltage VDD (this is referred to as self-boost). Further, at a time t5, the voltage Vpgm(N+1) is transferred to the selected word line WL32. However, as the potential of the channel has risen due to the above-mentioned self-boost, a negative charge that causes a threshold variation is not injected into the floating gate. That is, the threshold voltage shown in FIG. 2 is kept in the “B” state (the voltage Vth2) if, for example, N=2.

When the potential of the selected bit line BL is set to the zero potential by the sense amplifier 4 at the time t1, the potential of the channel is set to the zero potential. Thus, if the write voltage Vpgm(N+1) is transferred to the selected word line WL at the time t5, the negative charge that causes a threshold variation is injected into the floating gate, and the threshold voltage shown in FIG. 2 changes to a higher threshold distribution (“C” state). When, for example, N=3, the threshold voltage changes from the “C” state to the “D” state.

Although the data “1” is written into the memory cell transistor MT before the start of the next writing operation in the example described above, this embodiment is not limited to this example. That is, the data “1” does not have to be written into the memory cell transistor MT provided in the block BLK before the start of the next writing operation. In this case, for example, the “A” state may be set in the first writing, and the “C” state (data “1”) may be written in the next writing.

When N=1, the number of times of writing is one, so that the threshold distribution of the memory cell transistor MT is set to the “erased” state before data writing (see FIG. 3). In this case, the operations in steps S1 and S2 are omitted, and when the first data writing is performed in step S3, the state distribution of the memory cell transistor MT is changed from the “erased” state to the “A” state. Further, the operations in and after step S4 are performed.

While the writing of the data “1” and “0” is described above by way of example, the operations from the time t1 to t2 are the same as the data read and verify operations. In the data read and verify operations, the voltages transferred to the word line WL at the times t4 and t5 may be the voltage Vcgr and the voltage Vread. That is, in steps S1 and S6, the potentials of the word line WL at the times t4 and t5 are set at the voltage Vcgr and the voltage Vread in FIG. 6.

Furthermore, the data is read from the memory cell transistor MT in which the data is written in step S5 (S6), and the write operation is performed until all of the memory cell transistors MT in the block BLK where the memory cell transistor MT targeted for writing is provided hold data “1” (S5, S6, S7). That is, when there is even one memory cell transistor MT holding data “0” in the block BLK (S7, NO), the operations in step S5 to S7 are performed until the memory cell transistor MT holds data “1”.

<Read Operation>

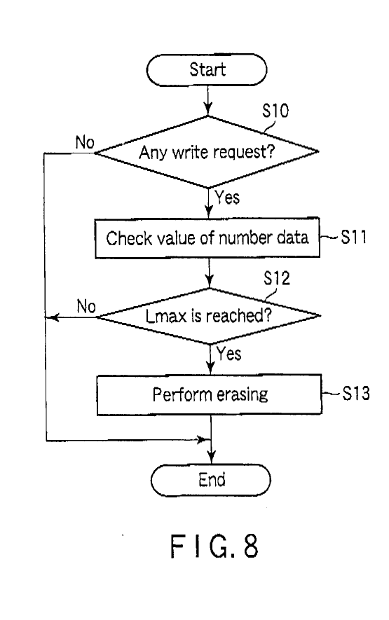

The read operation in step S1 in FIG. 5 will be explained below. FIG. 7 is a conceptual diagram of read operation of “0” or “1” data according to the amount of charge held in the memory cell transistor MT and the number of times of writing.

In the following explanation, N=2 is assumed. That is, the memory cell transistor MT is in the “A” state or the “B” state. First, the sense amplifier 4 charges the bit line BL to a fixed voltage. The voltage Vcgr(N−1) is then applied to the word line WL. When the threshold voltage of the memory cell transistor MT is lower than the voltage Vcgr(N−1), that is, if the threshold voltage of the memory cell transistor MT is V01 (“A” state), the memory cell transistor MT is turned on. That is, the bit line BL and the source line SL are connected so that the bit line BL is discharged. The sense amplifier 4 senses this voltage and thereby judges that the memory cell transistor MT holds data “0”.

On the contrary, when the threshold voltage of the memory cell transistor MT is higher than the read level, that is, if the threshold voltage of the memory cell transistor MT is Vth2 (“B” state), the memory cell transistor MT is turned off. That is, the bit line BL and the source line SL are not connected. The sense amplifier 4 senses the potential of the bit line BL and judges that the memory cell transistor MT holds data “1”.

Similarly, in the reading of data in S7, the voltage Vcgr2 is transferred to the memory cell transistor MT. In this case, if the threshold voltage of the memory cell transistor MT is V12 (“B” state), the sense amplifier 4 judges that the memory cell transistor MT holds data “0”. On the other hand, if the threshold voltage of the memory cell transistor MT is V23 (“C” state), the sense amplifier 4 judges that the memory cell transistor MT holds data “1”.

<Erase Operation>

Now, the erase operation performed by the controller 9 is described with reference to FIG. 8. FIG. 8 is a flowchart showing the operation of the controller 9.

As shown in FIG. 8, when a new write request is issued (S10, YES), the controller 9 refers to the number data 91 to check the number data in the block BLK where the memory cell transistor MT targeted for writing the data is provided (S11, S12).

As a result, if the number data has reached the maximum permitted overwriting count LMAX (S12, YES), the controller 9 performs the erase operation, and changes the threshold voltage of the memory cell transistor MT to an erase voltage or the “A” state (S13). Further, the new data is written.

When the number data has not reached the maximum permitted overwriting count LMAX (S12, NO), the controller 9 does not perform the erase operation, and performs the write operation shown in FIG. 5.

<How to Set the Maximum Permitted Overwriting Count LMAX>

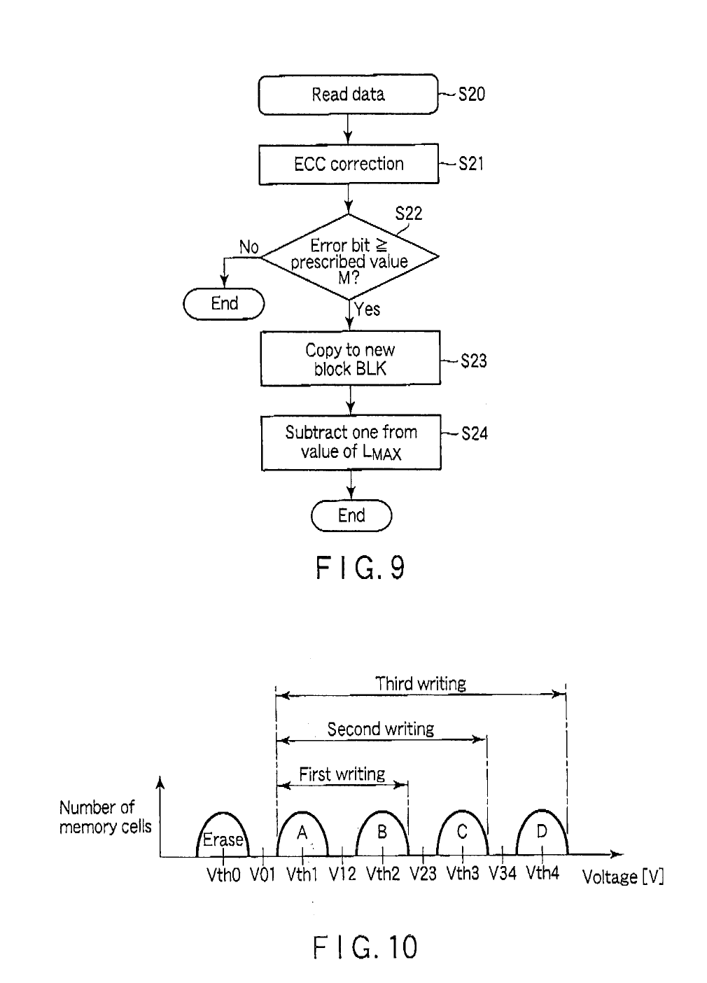

Now, how to set the LMAX is described with reference to FIG. 9. FIG. 9 is a flowchart showing the operation of decreasing the value of the LMAX held in the controller 9 when the error rate of the memory cell transistor MT is beyond a prescribed value.

As shown in FIG. 9, when a data read command is issued from the unshown host, the controller 9 performs the read operation corresponding to the number of times of writing as described above (step S20). The ECC circuit 5 performs an error correction for the read data (step S21). The data corrected by the ECC circuit 5 is transferred to the unshown host by the controller 9.

When error bit≧prescribed value M in step S22 (S22, YES), the controller 9 copies the data in the block BLK having a high error rate to a new block BLK (S23). The controller 9 then subtracts, for example, one from the value of the maximum permitted overwriting count LMAX of the corresponding block BLK (S24).

Furthermore, if error bit<prescribed value M in step S22 (S22, NO), the characteristics of the memory cell transistor MT is preferable so that no subtraction from the value of the maximum permitted overwriting count LMAX is performed, and the next reading is performed.

<Advantages According to this Embodiment>

The following advantages (1) to (4) may be obtained according to the semiconductor storage device of this embodiment.

(1) The writing speed may be improved:

According to the semiconductor storage device of this embodiment, the threshold of the memory cell transistor MT is changed level by level, for example, from the “erased” state to the “A” state, from the “A” state to the “B” state, from the “B” state to the “C” state, and from the “C” state to the “D” state. Here, a change to a threshold distribution one level higher is referred to as a one-level rise.

Alternatively, the threshold is changed two levels at a time, for example, from the “erased” state to the “B” state, from the “A” state to the “C” state, and from the “B” state to the “D” state. In this case, the threshold distribution is raised two levels at the maximum.

On the other hand, if the threshold distribution is changed from the “erased” state to the “D” state or from the “A” state to the “D” state, that is, changed as many as three levels, the time of a write voltage applied to the memory cell transistor MT necessary for this change is long.

In contrast, the threshold distribution is changed two levels at the maximum in this embodiment as described above. That is, the amount of change of the threshold distribution is reduced. Therefore, the time of the application of the write voltage to the memory cell transistor MT necessary for this change is naturally shorter than that for the three-level change. That is, an improvement in the writing speed may be expected.

In the writing of data into the memory cell transistor MT holding multi-value data, the threshold distribution may be changed, for example, three levels higher from the “erased” state. In this case, the time of the application of the write voltage to vary the threshold distribution is increased. In contrast, according to the semiconductor storage device of this embodiment, the application time is about the same as that for a memory cell transistor MT for one-bit writing. Thus, an improvement in the writing speed may be expected.

(2) The writing speed may be improved:

According to the semiconductor storage device of this embodiment, the number of times of writing data is unified by the block BLK unit as described above. That is, when data is written per block BLK, adjacent blocks BLK are different in the number of times of data writing. However, when attention is focused on a certain block BLK, adjacent memory cell transistors MT are equal in the number of times of data writing. That is, for example, if the number of times of writing is one, the threshold level is set to the “A” state or the “B” state, but there is no great difference of threshold levels between the adjacent memory cell transistors MT in contrast with a multi-value memory. That is, it is possible to suppress program disturb wherein data is written into the memory cell transistor MT to change the threshold level of the memory cell transistor MT to a desired threshold level and the threshold distribution of the adjacent memory cell transistor MT is varied accordingly.

Various measures are taken to prevent such a situation. For example, one method is to write data into the memory cell transistor MT at a time, and then only write data into the adjacent memory cell transistor MT alone and again apply a write voltage to the former memory cell transistor MT to correct the threshold distribution.

However, according to this embodiment, the program disturb may be suppressed in the first place, so that there is no need to again apply a write voltage to the memory cell transistor MT to correct the varied threshold distribution in contrast with the above-mentioned method. That is, the processing up to the end of writing may be accelerated.

(3) The writing accuracy may be improved.

According to the semiconductor storage device of this embodiment, the number of times of writing into the memory cell transistor MT is unified by the block BLK unit as described above, and the program disturb is not easily caused. That is, the threshold distribution held in the memory cell transistor MT is not easily shifted, and the accuracy of writing data is improved.

(4) Declining of the memory cell transistor MT is prevented.

According to the semiconductor storage device of this embodiment, if data is written into the same memory cell transistor MT, for example, three times and then data has to be further written, the data in this memory cell transistor MT is erased. That is, the number of times of applying an erase voltage of, for example, 20 V to the memory cell transistor MT is reduced. As a result, the memory cell transistor MT does not easily declining, and the memory cell transistor MT may be used for a long time. That is, high reliability of the characteristics of the memory cell transistor MT may be maintained.

<Modification>

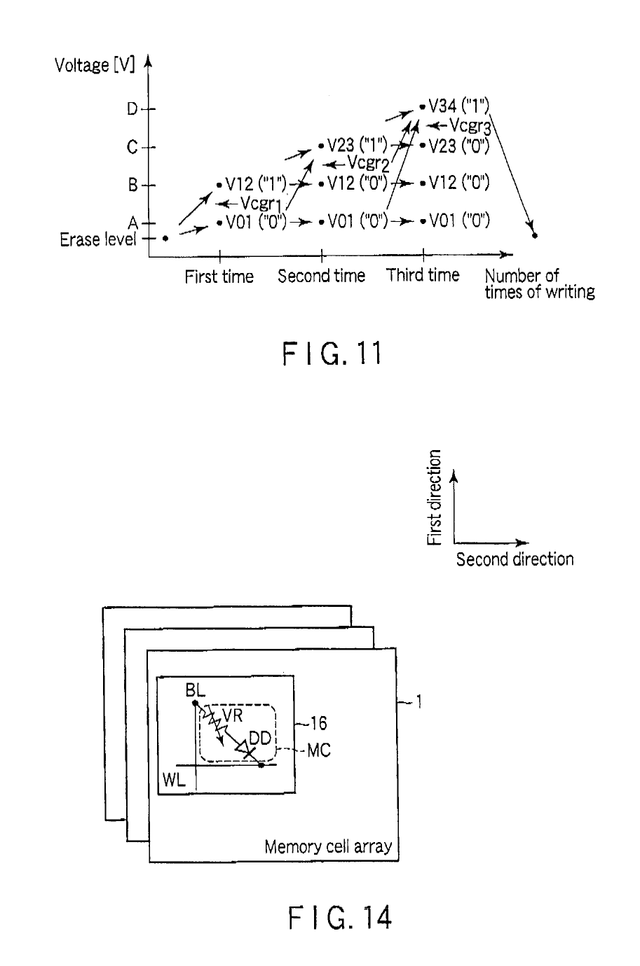

Now, a modification of the semiconductor storage device according to the first embodiment is described with reference to FIG. 10 and FIG. 11. FIG. 10 is a conceptual diagram of a threshold distribution of a memory cell transistor MT according to the modification when data is written in this memory cell transistor MT. FIG. 11 is a conceptual diagram showing data (“0” or “1”) read according to the read level in the threshold distribution of the memory cell transistor MT shown in FIG. 10.

In FIG. 10, the vertical axis indicates the number of the memory cell transistors MT, and the horizontal axis indicates a voltage. As shown in FIG. 10, the threshold distributions that may be made by the memory cell transistor MT according to the modification are the “erased” state, the “A” state, the “B” state, the “C” state, and the “D” state in ascending order. In this case as well, the “erased” state is a negative voltage, and is set to a positive voltage (the “A” state, the “B” state, the “C” state, and the “D” state) by injecting a charge into the floating gate of the memory cell transistor MT. As in the first embodiment described above, the “A” state may have the same potential as the “erased” State. In this case, the “A” state is the negative voltage.

As shown in FIG. 10, the memory cell transistor MT according to the modification has the state distribution of the “A” state or the “B” state in the first data writing as in the first embodiment described above. However, in the second data writing, the memory cell transistor MT according to the modification has the state distributions of the “A” state, the “B” state, or the “C” state. In the third data writing, the memory cell transistor MT according to the modification has the state distributions of the “A” state, the “B” state, the “C” state, or the “D” state.

That is, when there is no need to hold data “1” (the threshold level is higher than the memory cell transistor MT holding data “0”) in the memory cell transistor MT, the threshold level is not particularly changed, and the data “0” is maintained.

Next, the value of the held data read according to the threshold distribution of the memory cell transistor MT is described with reference to FIG. 11. In FIG. 11, the vertical axis indicates the threshold level of the memory cell transistor MT, and the horizontal axis indicates the number of times of writing. The details covered in FIG. 7 are not described.

As shown in FIG. 11, the voltage Vcgr2, for example, is used to read the memory cell transistor MT that has changed from the “A” state or the “B” state to the “A” state, the “B” state, or the “C” state as a result of the second data writing. If the state distribution of the memory cell transistor MT is the “C” state (voltage V23), the sense amplifier 4 judges that the memory cell transistor MT holds data “1”.

On the other hand, if the state distribution of the memory cell transistor MT is the “A” state or the “B” state (voltage V01 or V12), the sense amplifier 4 judges that the memory cell transistor MT holds data “0”.

Similarly, the voltage Vcgr3, for example, is used to read the memory cell transistor MT that has changed from the “A” state, the “B” state, or the “C” state to the “A” state, the “B” state, the “C” state, or the “D” state as a result of the third data writing. If the state distribution of the memory cell transistor MT is the “D” state (voltage V34), the sense amplifier 4 judges that the memory cell transistor MT holds data

On the other hand, if the state distributions of the memory cell transistor MT are the “A” state, the “B” state, and the “C” state (voltage V01, V12 or V23), the sense amplifier 4 judges that the memory cell transistor MT holds data “0”.

<Advantages According to the Modification>

The following advantages may be obtained according to the semiconductor storage device of the modification of this embodiment in addition to the advantages (3) and (4).

(5) Power consumption may be reduced.

According to the semiconductor storage device of the modification of this embodiment, the threshold voltage is not varied when data “1” is not written in each time of writing as described above. That is, as has been shown in the first embodiment described above, the threshold level is not changed one level higher before the next writing, and the threshold level is changed only when data “1” is written. That is, if there is no need, it is not necessary to apply, to the memory cell transistor MT, a high write voltage for changing the threshold level to, for example, the “B” state or the “C” state as has been described in the first embodiment. Thus, the change amount of the threshold level of the memory cell transistor MT is small, and power consumption may be reduced.

(6) Characteristic declining of the memory cell transistor MT may be prevented.

According to the semiconductor storage device of the modification of this embodiment, the threshold distribution of the memory cell transistor MT is maintained when there is no need to write data “1” as has been described with reference to FIG. 10 and FIG. 11. That is, no high write voltage Vpgm is applied to the memory cell transistor MT except when necessary. Thus, the number of times of writing into the memory cell transistor MT is reduced, and characteristic declining of the memory cell transistor MT may be prevented.

### Second Embodiment

Now, a memory system according to a second embodiment is described. In the memory system according to this embodiment, the NAND-type flash memory described by way of example in the first embodiment and its modification is applied to a personal computer (PC) comprising, for example, a solid state drive (SSD).

<Overall Configuration Example>

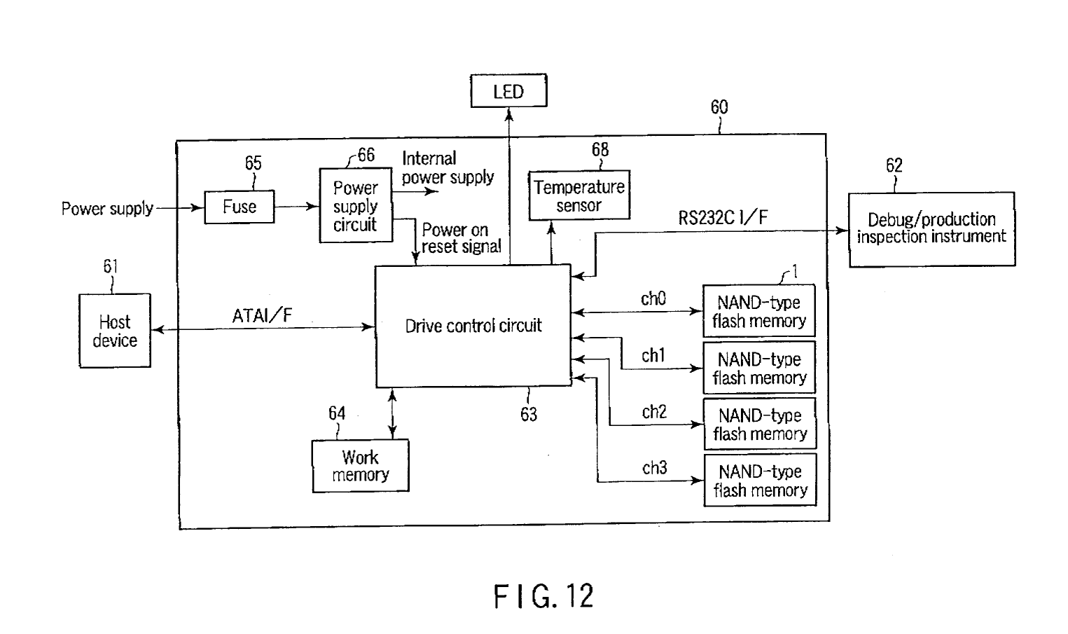

The memory system according to this embodiment is described with reference to FIG. 12. FIG. 12 is a conceptual diagram showing the internal configuration of the memory system according to this embodiment. As shown in FIG. 12, a memory system 60 is connected to a host device 61 such as a personal computer or a central processing unit (CPU) core via a memory connection interface such as an ATA interface (ATA I/F), and functions as an external memory of the host device 61. The memory system 60 may also send/receive data to/from a debug/production inspection instrument 62 via a communication interface such as an RS232C interface (RS232C I/F).

The memory system 60 includes NAND-type flash memories 1 as the nonvolatile semiconductor memories described above, a drive control circuit 63 as a host controller corresponding to the controller 9 in the first embodiment described above, a work memory (DRAM) 64 as a volatile semiconductor memory, a fuse 65, a power supply circuit 66, a status indication LED 67, and a temperature sensor 68 for detecting the temperature inside the drive.

The power supply circuit 66 generates different internal direct-current power supplies out of an external direct-current power supply supplied from a power supply circuit on the host device 61 side, and supplies these internal direct-current power supplies to the respective circuits in the memory system 60. The power supply circuit 66 detects the rise of the external power supply, generates a power on reset signal, and supplies the signal to the drive control circuit 63.

The fuse 65 is provided between the power supply circuit on the side of the host device 61 and the power supply circuit 66 inside the memory system 60. When an over-current is supplied from the external power supply, the fuse 65 is blown, and wrong operations of the internal circuits are prevented.

The memory system 60 includes the NAND-type flash memories 1 (four NAND-type flash memories 1 are shown by way of example in this embodiment), and the four NAND-type flash memories 1 are connected to the drive control circuit 63 by four channels (ch0 to ch3). The four NAND-type flash memories 1 are capable of parallel operation or interleave operation by the four channels (ch0 to ch3).

The work memory 64 functions as, for example, a data transfer cache and a work space memory between the host device 61 and the NAND-type flash memories 1. The contents to be stored in the work space memory of the work memory 64 include, for example, a master table (snapshot) in which various management tables stored in the NAND-type flash memories 1 are expanded at the start of operation, or log information which is a change difference of the management table.

A nonvolatile random access memory such as a ferroelectric random access memory (FeRAM), a magnetoresistive random access memory (MRAM), or a phase-change random access memory (PCRAM) may be used instead of the work memory 64. When the nonvolatile random access memory is used, the operation of evacuating, for example, the various management tables to the NAND-type flash memories 1 when power is off may be partly or totally omitted.

The drive control circuit (host controller) 63 controls data transfer between the host device 61 and the NAND-type flash memory 1 via the work memory 64, and also controls each module in the memory system 60. The drive control circuit 63 also functions to supply a status indication signal to the status indication LED 67, and to supply a reset signal and a clock signal to various components in the drive control circuit 63 and the memory system 60 in response to the power on reset signal from the power supply circuit 66. The drive control circuit 63 serves as the host controller for the NAND-type flash memory 1. That is, the drive control circuit 63 has the function of the controller 9 in the first embodiment as described above. Details of the function have been described in the first embodiment and are not described here.

<Details of the Work Memory 64>

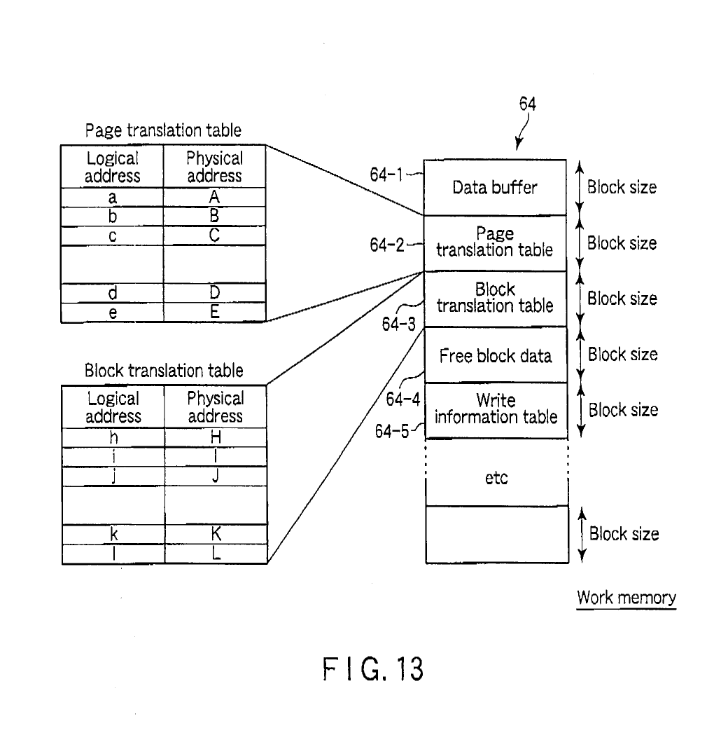

Now, an internal configuration example of the work memory 64 is described with reference to FIG. 13. As shown in FIG. 13, the work memory 64 includes a data buffer 64-1, a page translation table 64-2, a block translation table 64-3, a free block data 64-4, and a write information table 64-5.

The data buffer 64-1 functions to temporarily hold data.

The page translation table 64-2 holds page-by-page logical addresses and corresponding physical addresses, as shown in the left center of FIG. 13.

The block translation table 64-3 holds block-by-block logical addresses and corresponding physical addresses, as shown in the lower left of FIG. 13.

The free block data 64-4 is a region in which necessary data may be freely stored.

The write information table 64-5 holds the information included in the controller 9 in the first embodiment described above. Specifically, the write information table 64-5 holds a mode (mode information indicating a mode 1 or a mode 2) of writing into a block BLK, the number of times of writing into the block BLK at the moment, and a maximum permitted overwriting count (LMAX). There are as many write information tables 64-5 as the blocks BLK formed in the NAND-type flash memory 1. That is, in this embodiment, the four NAND-type flash memories are provided, so that the number of entries in the write information tables 64-5 is four times as large as the number of blocks in one NAND-type flash memory.

<Advantages According to this Embodiment>

The advantages obtained in the first embodiment and its modification may also be obtained by the memory system according to this embodiment. Thus, the advantages (1) to (5) may be obtained as described above. The advantages are occurred in the case of the PC equipped with an SSD described by way of example in this embodiment. That is, in an electronic device such as the PC which deals with a great amount of data, once stored data is newly overwritten (updated) more frequently than in a storage medium such as an SDTM or an MMC. In other words, data is frequently written into a memory cell transistor MT. Moreover, the amount of data to be dealt with is increasing under this situation. Although multi-value memories are currently developed and used as a measure of enabling a great amount of data to be stored in one memory cell transistor MT, there is a limit to the use as described above.

Under these circumstances, in the memory system according to this embodiment, data may be written into the same memory cell transistor MT more than one time before an erase operation is performed. Thus, advantageously, the memory cell does not easily deteriorate (degrade) and is durable as compared with a memory cell in which an erase operation and write operation are performed the same number of times upon every writing of new data.

Furthermore, in the memory system according to this embodiment, the write mode may be changed to the mode 1 or the mode 2 depending on the characteristics of the memory cell transistor MT as has been described in the first embodiment. That is, in the first embodiment described above, when writing is performed in a multi-value mode of, for example, 2 bits (4 values), 3 bits (8 values), or 4 bits (16 values), the amount of information that may be stored is decreased, for example, from 3 bits to 2 bits according to the characteristics of the memory cell transistor MT, that is, the spread of the threshold distribution (a voltage difference between a high voltage side and a low voltage side). Instead, the write mode is changed so that, out of the same number of states in the existing 3-bit representation including the “A” state, the “B” state, the “C” state, the “D” state, the “E” state, the “F” state, the “G” state, and the “H” state, the last “H” state is eliminated. Further, a read voltage Vcgr and the number of times of writing indicated by number data 91 are used to judge whether each of the “A” state to the “G” state corresponds to data “0” or data “1”. As a result, when, for example, the characteristics of the memory cell transistor MT have deteriorated and the resolution for reading the threshold distribution held by the memory cell transistor MT is reduced, the mode is turned as described above to prevent a rapid decrease of the amount of data held in the memory cell transistor MT.

### Third Embodiment

Now, a semiconductor storage device according to a third embodiment is described. In the semiconductor storage device according to this embodiment, the NAND-type flash memory described by way of example in the first embodiment and its modification is used as, for example, a resistance random access memory (ReRAM). That is, peripheral circuits that constitute the NAND-type flash memory described in the first embodiment, such as, the row decoder 2, the driver circuit 3, the voltage generator 8, the sense amplifier 4, the ECC circuit 5, the data input/output circuit 6, and the controller 9 have the same configuration in this embodiment and are therefore not described.

<Overall Configuration Example>

FIG. 14 is a block diagram of the ReRAM as a memory cell MC according to this embodiment. As shown in FIG. 14, a memory cell array 1 includes bit lines BL provided along a first direction, word lines WL provided along a second direction intersecting at right angles with the first direction, and the memory cells MC provided at the intersections of the bit lines BL and the word lines WL. An assembly of the memory cells MC forms a unit referred to as a MAT 16.

Each of the memory cells MC includes a rectification element (diode) DD and a variable resistance element VR. The cathode of the diode DD is connected to the word line WL, and the anode of the diode DD is connected to the bit line BL via the variable resistance element VR. The variable resistance element VR has a structure in which, for example, a recording layer, a heater layer, and a protective layer are stacked in order on the diode DD.

The memory cells MC arranged in the same row in the memory cell array 1 are connected to the same word line WL, and the memory cells MC arranged in the same column are connected to the same bit line BL. The word lines WL, the bit lines BL, and the memory cells MC are provided along a third direction (the direction perpendicular to the surface of a semiconductor substrate) intersecting at right angles with both the first and second directions. That is, the memory cell array 10 has a structure in which the memory cells MC are three-dimensionally stacked. Each layer of the memory cell in this three-dimensional structure may hereinafter be referred to as a memory layer.

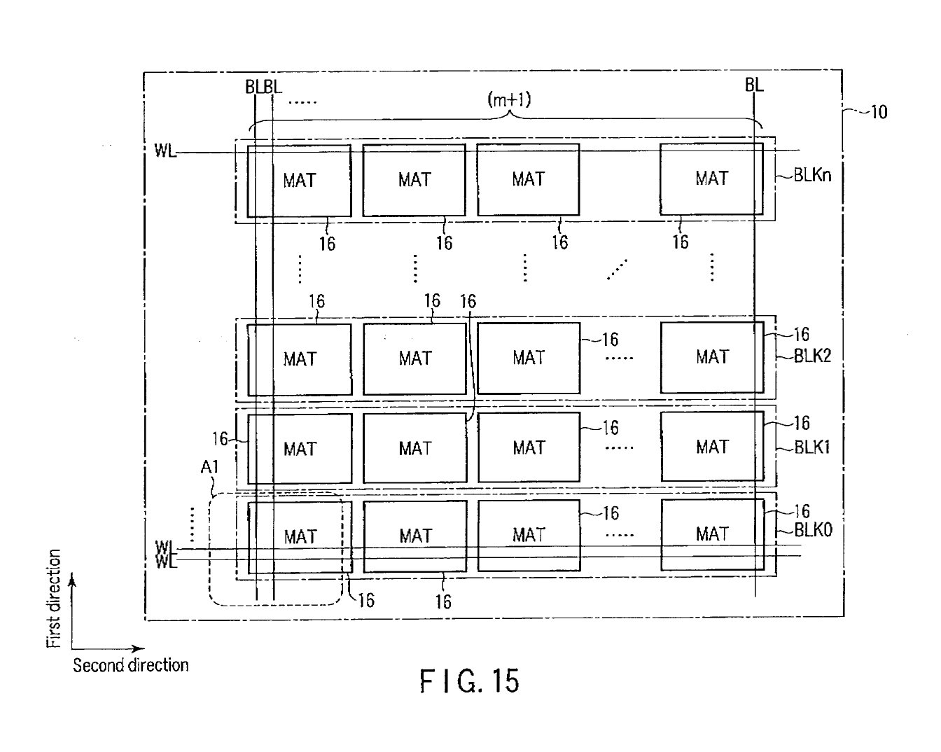

Now, a detailed configuration example of the above memory cell array 1 is described with reference to FIG. 15. FIG. 15 is a block diagram of the memory cell array 1, and only shows one memory cell layer.

As shown, the memory cell array 1 according to this embodiment includes (m+1)×(n+1) MATs 16 arranged in a matrix form (m and n are natural numbers equal to or more than 1). The memory cells MC are included in each of the MATs 16 as described above, and are arranged in a matrix form. For example, one MAT 16 includes, for example, 16 word lines WL and 16 bit lines BL. That is, one MAT 16 includes (16×16) memory cells MC. Moreover, the memory cell array 10 includes 16×(m+1) bit lines BL and 16×(n+1) word lines WL. The MATs 16 in the same row (i.e., the MATs 16 sharing the word line WL) constitute block BLK. Thus, the memory cell array 10 is constituted by blocks BLK0 to BLKn. The blocks BLK0 to BLKn will be hereinafter referred to simply as a block BLK when not distinguished from one another.

Although one memory cell layer includes the MATs 16 in this embodiment described, one memory cell layer may include one MAT 16. Moreover, the number of memory cells MC included in one MAT 16 is not exclusively (16×16). Further, a row decoder 11 and a sense amplifier 12 may be provided for each MAT 16 or may be shared by the MATs 16. The latter case is described below as an example.

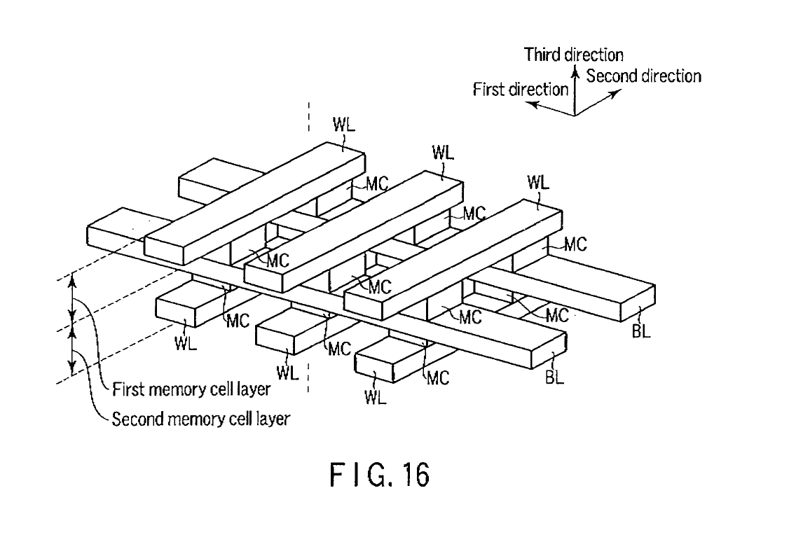

FIG. 16 is a perspective view of partial regions of the memory cell arrays 1, and shows how the memory cell arrays 1 having the configuration described above are three-dimensionally constructed. As shown, the memory cell arrays 1 according to this embodiment (a first memory cell layer, a second memory cell layer, . . . ) are stacked in a direction (third direction) perpendicular to the surface of the semiconductor substrate. Although a word line WL, a memory cell MC, a bit line BL, a memory cell MC, a word line WL, are formed in this order in the example of FIG. 16, sets of a word line WL, a memory cell MC, and a bit line BL may be stacked via interlayer insulating films.

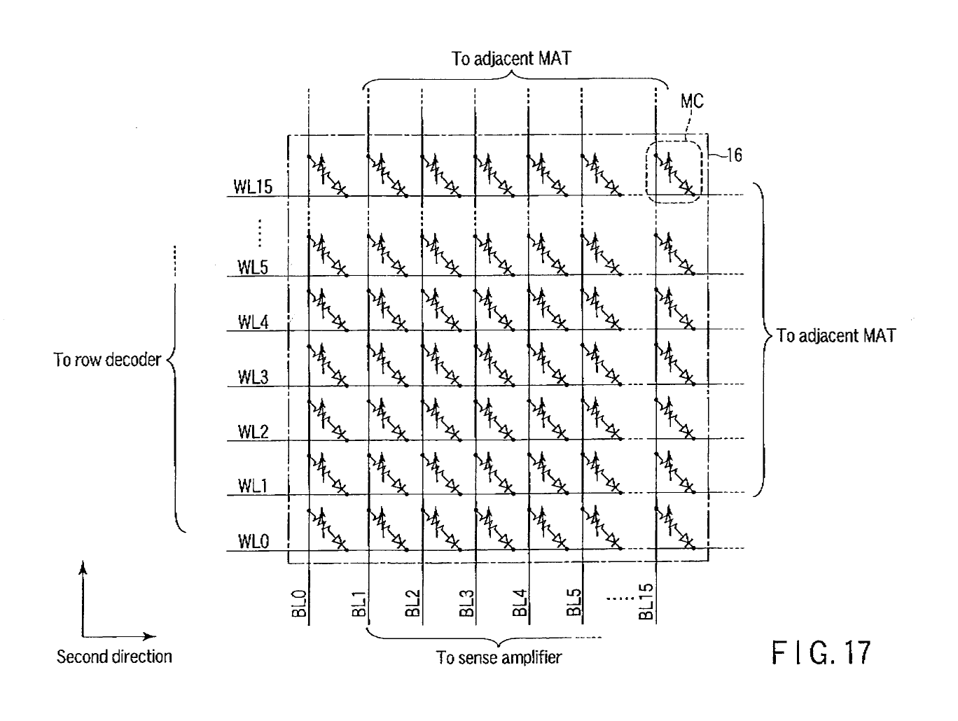

FIG. 17 is a circuit diagram of the memory cell array 1 described above, and particularly shows a region corresponding to a region A1 in FIG. 15 in one memory cell layer.

As shown, the bit lines BL and the word lines WL are formed across the MATs 16 in the memory cell array 1.

The MAT 16 includes 16 bit lines BL and 16 word lines WL as described above. Moreover, there are (m+1)×(n+1) MATs 16 as described above. That is, word lines WL(16i) to WL(16i+15) are formed in a given block BLKi. Bit lines BL(16j) to BL(16j+15) are formed in each of the MATs 16 included in a given block BLK. However, i=0 to n and j=0 to m.

The memory cells MC are formed at the intersections of the bit lines BL and the word lines WL, respectively.

The word lines WL are connected to an unshown row decoder 2. On the other hand, the bit lines BL0 to BLn are connected to an unshown sense amplifier 4.

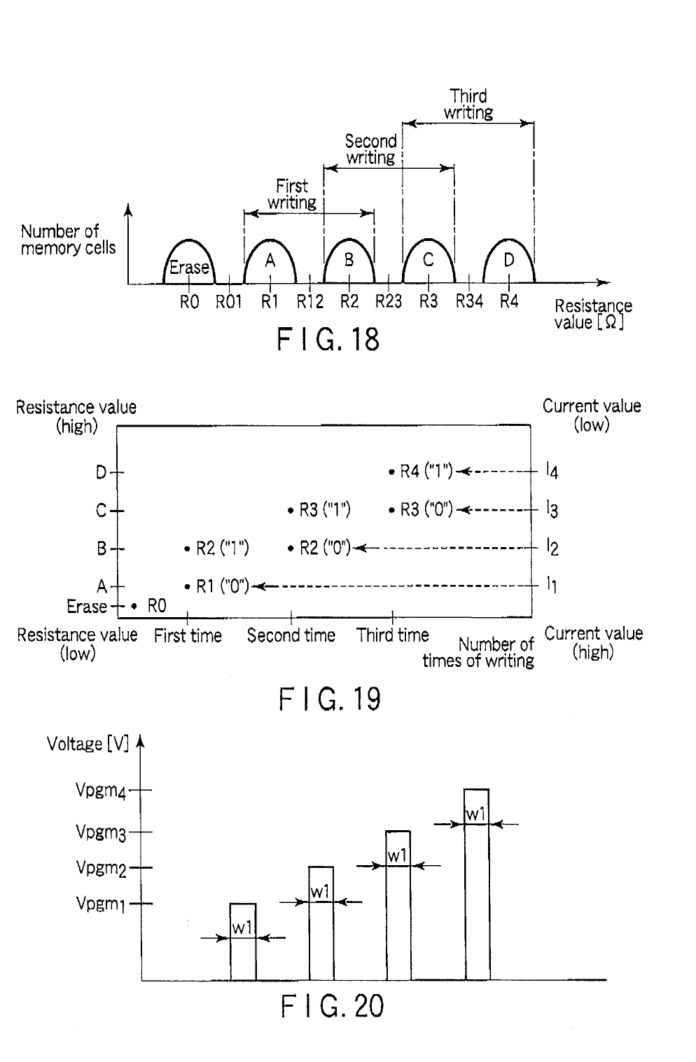

Now, the characteristics of the memory cell MC are described with reference to FIG. 18. As shown in FIG. 18, the memory cell MC holds data corresponding to the resistance value of the variable resistance element VR. The variable resistance element VR may have a low-resistance state at a resistance value of 1 k to 10 kΩ, and a high-resistance state at a resistance value of 100 k to 1 MΩ.

The high-resistance state is a state that holds, for example, the “A” state, the “B” state, the “C” state, and the “D” state in the first embodiment described above, and is a data-written state (program level). That is, the “A” state, the “B” state, the “C” state, and the “D” state are set between resistance values ranging, for example, from 100 k to 1 MΩ. A current corresponding to this resistance value runs through the memory cell MC.

The low-resistance state is the “erased” state (erase level) in the first embodiment described above, and is a data-erased state. As in the first embodiment described above, the “A” state and the “erased” state may be at the same level.

Now, the data held in the memory cell MC is described with reference to FIG. 19. FIG. 19 is a graph showing a conceptual diagram of the resistance value of the memory cell MC, a current running through the variable resistance element VR according to the resistance value, and the value of data held in the memory cell MC according to the current and the number of times of writing into the memory cell MC.

As described above, the memory cell MC holds the “A” state, the “B” state, the “C” state, and the “D” state according to the number of times of writing. As shown in FIG. 19, at a resistance value R1 indicating the “A” state, a current I1 runs through the variable resistance element VR. At a resistance value R2 indicating the “B” state, a current I2 runs through the variable resistance element VR. At a resistance value R3 indicating the “C” state, a current I3 runs through the variable resistance element VR. At a resistance value R4 indicating the “D” state, a current I4 runs through the variable resistance element VR. These currents I1 to I4 satisfy current I1>current I2>current I3>current I4.

That is, when, for example, writing is performed one time, the memory cell MC is set to the resistance value of the “A” state or the “B” state. When the current I1 runs through the variable resistance element VR of this memory cell MC, the memory cell MC holds data “0”. When the current I2 runs, the sense amplifier 4 judges that the memory cell MC holds data “1”.

Even if the current I2 runs through the variable resistance element VR of the memory cell MC, data written into the memory cell MC for the second time is judged to be data “0”. Other numbers of times of writing and how to judge data held in the memory cell MC by the values of currents running according to those numbers of times are similar and are therefore not described.

Now, a write voltage applied to the memory cell MC is described with reference to FIG. 20. As described above, the resistance value of the memory cell changes with the intensity and application time (pulse width) of the write voltage. Although attention is focused on the voltage in the following explanation, the value of a current running through the variable resistance element VR may be changed to change its resistance value.

As shown in FIG. 20, the write voltages include a voltage Vpgm1 to a voltage Vpgm4. For example, the voltage Vpgm1 corresponding to a pulse width w1 is applied to the memory cell MC to set the “A” state. The voltage Vpgm2 corresponding to the pulse width w1 is applied to the memory cell MC to set the “B” state. The voltage Vpgm3 corresponding to the pulse width w1 is applied to the memory cell MC to set the “C” state. The voltage Vpgm4 corresponding to the pulse width w1 is applied to the memory cell MC to set the “D” state. The values of the voltage Vpgm1 to the voltage Vpgm4 may be the same as or different from the values of the write voltage Vpgm1 to the voltage Vpgm4 in the first embodiment described above.

Moreover, for example, the pulse width for applying the voltage Vpgm1 to the memory cell MC may be made greater than w1 to set the resistance value of the memory cell MC to one of the “B” state to the “D” state.

<Advantages According to this Embodiment>

The advantages obtained in the first embodiment and its modification may also be obtained by the semiconductor storage device according to this embodiment. Thus, the advantages (1) to (6) may also be obtained in this embodiment. That is, in this embodiment, threshold distributions are produced according to the resistance value of the variable resistance element VR of the memory cell MC. A given voltage is applied to this variable resistance element, and a current that runs through the memory cell MC accordingly is detected by the sense amplifier 4, such that the data held in the memory cell MC is recognized. In this embodiment, the threshold distribution only changes one level or two levels as in the first embodiment and its modification. Consequently, a low write voltage has only to be applied to the variable resistance element VR, and reduced power consumption and a shorter writing time may be expected.

The “erased” state and the “A” state may have the same threshold voltage in the first embodiment and its modification. In this case, the “A” state is the negative voltage.

If N is equal to 1 in this case, the operation in step S3 in FIG. 5 may be omitted in the first embodiment described above. The reason for this is that as the “erased” state and the “A” state have the same threshold, there is no need to transfer a write voltage Vprm1 to the memory cell MC to change from the “erased” state to the “A” state.

Moreover, data may be written into one block BLK in this method (mode 2), and data may be written into another block BLK in the conventional method (mode 1). In other words, any write modes may be mixed in the blocks BLK.

Furthermore, the embodiment described above includes the following aspects.

(1) A semiconductor storage device comprises:

a memory cell array in which memory cells hold data “0” or “1” according to a read level are arranged along row and column directions;

a controller which counts the number of times N (N: an integral number equal to or more than 0) of sequentially writing the data into the memory cell and which transfers, to the memory cell, a write voltage and a read voltage that are variable according to the number of times N; and

a voltage generator which generates the write voltage and uses this write voltage to write at least “1” bit data into the memory cell and which generates the read voltage and reads the at least “1” bit data from the memory cell,

wherein when the N-th (≧2) write request is issued to the memory cell,

the controller causes the voltage generator to generate the read voltage corresponding to an (N−1)th time, and uses this read voltage to read the “1” bit data from the memory cell,

according to the data corresponding to the write request, the controller causes the voltage generator to generate the write voltage which changes to a threshold voltage higher than a threshold voltage of the memory cell at which the data is read in the (N−1)th reading, and

when the N-th (≧2) write request to the memory cell has reached a prescribed value, the controller erases the data held in the memory cell.

(2) The semiconductor storage device according to the aspect of (1), wherein

the memory cell includes a rectification element, and a variable resistance element capable of changing to multiple resistance states,

the voltage generator includes a sense amplifier which senses a current running through the memory cell according to the resistance states, and

the controller reads the data held in the memory cell according to the number of times N and the current sensed by the sense amplifier.

(3) The semiconductor storage device according to the aspect of (2), wherein

the variable resistance element is capable of changing to one of an erased state, a first state, a second state, and a third state in ascending order of resistance value,

the voltage generator includes a pulse having a first width, and generates, as the write voltage, a first voltage, a second voltage higher than the first voltage, and a third voltage higher than the second voltage,

the first voltage is a voltage capable of changing from the erased state to the first state,

the second voltage is a voltage capable of changing from the erased state or the first state to the second state, and

the third voltage is a voltage capable of changing from the second state to the third state.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor storage device comprising:
a memory cell array in which each of memory cells capable of holding data “0” or “1” according to a read level are arranged along row and column directions;
a controller which counts the number of times N (N: an integral number equal to or more than 0) of sequentially writing the data into the memory cell and which transfers, to the memory cell, a write voltage and a read voltage which are variable according to the number of times N; and
a voltage generator which generates the write voltage and uses this write voltage to write at least “1” bit data into the memory cell and which generates the read voltage and reads the at least “1” bit data from the memory cell,
wherein when the N-th (≧2) write request is issued to the memory cell,
the controller causes the voltage generator to generate the read voltage corresponding to an (N−1)th time, and uses this read voltage to read the “1” bit data from the memory cell,
according to the data corresponding to the write request, the controller causes the voltage generator to generate the write voltage which changes a threshold voltage of the memory cell to higher a threshold voltage than a threshold voltage of the memory cell at which the data is read in the (N−1)th reading, and
when the N has reached a prescribed value, the controller erases the data held in the memory cell.

2. The device according to claim 1, wherein
the memory cell is capable of changing to any one state of a first state, a second state, and a third state which are separated from one another in ascending order of threshold voltage,
the controller holds a maximum overwriting count which allows the data to be sequentially written into the memory cell, and
the controller subtracts one from the maximum overwriting count according to a potential difference between an upper threshold voltage in the first state and a lower threshold voltage in the second state or according to a potential difference between an upper threshold voltage in the second state and a lower threshold voltage in the third state.

3. The device according to claim 1, wherein
when the threshold voltage of the memory cell is lower than the (N−1)th read voltage as a result of reading the “1” bit data,
the controller changes the threshold voltage of the memory cell to a threshold voltage higher than the (N−1)th read voltage, and then performs the N-th writing into the memory cell.

4. The device according to claim 1, wherein
the controller manages the number of times N block by block, the block including the memory cell arrays and being an erase unit of the data written in the memory cell.

5. The device according to claim 1, wherein
the controller manages the number of times N block by block, the block including the memory cell arrays and being an erase unit of the data written in the memory cell, and
when all of the memory cells provided in the block hold data “1”, the controller performs the N-th writing into the memory cell.

6. The device according to claim 1, wherein
the memory cell is capable of holding M-value data (≧four values) or two-value data corresponding to the read level, and
the controller is capable of turning to a first method or a second method, the first method reading the data “0” or “1” from the memory cell according to the read level, the second method reading any one of the M-value data.

7. The device according to claim 2, wherein
the maximum overwriting count varies block by block, the block including the memory cell arrays and being an erase unit of the data written in the memory cell,
the memory cell is capable of holding M-value data (≧four values) or two-value data corresponding to the read level,
the controller manages the maximum overwriting count which varies block by block, and
the controller is capable of turning to a first method or a second method, the first method reading the data “0” or “1” from the memory cell according to the read level, the second method reading any one of the M-value data.

8. The device according to claim 2, wherein
the voltage generator generates a first voltage and a second voltage as the write voltages, the first voltage changing the threshold voltage of the memory cell from the first state to the second state, the second voltage changing the threshold voltage of the memory cell from the first state or the second state to the third state and being higher than the first voltage,
the voltage generator generates a third voltage and a fourth voltage as the read voltages, the third voltage being higher than the upper threshold voltage in the first state and lower than the lower threshold voltage in the second state, the fourth voltage being higher than the upper threshold voltage in the second state and lower than the lower threshold voltage in the third state, and
when new writing data is transferred, the controller transfers the third voltage or the fourth voltage to the memory cell according to the counted value and thereby reads the “1” bit data of “0” or “1” retained in the memory cell.

9. The device according to claim 7, wherein
the controller manages the first method or the second method block by block, the block including the memory cell arrays and being an erase unit of the data written in the memory cell.

10. A semiconductor storage device comprising;
a memory cell array in which a plurality of memory cells each capable of holding data “0” or “1” in accordance with a read level are arranged along row and column directions;
a controller which counts the number of times N (N: an integral number equal to or more than 0) of sequentially writing the data into each the memory cells and which transfers, to each the memory cells, a write voltage and a read voltage which are variable in accordance with the number of times N; and
a voltage generator which generates the write voltage and uses this write voltage to write at least “1” bit data into each the memory cells and which generates the read voltage and reads the at least “1” bit data from each the memory cells.

11. The device according to claim 10, wherein
the controller erases the data held in each the memory cells when the number of times N has reached a prescribed value.

12. The device according to claim 10, wherein
the potential of a channel of each the memory cells is set at a value higher than a zero potential when the data corresponding to the write request is data “0”, and
the threshold voltage of the memory cell to which the write voltage is applied is fixed.

13. The device according to claim 10, wherein
when a threshold voltage of the memory cell is lower than the (N−1)th read voltage as a result of reading the “1” bit data,
the controller changes the threshold voltage of the memory cell to a threshold voltage higher than the (N−1)th read voltage, and then performs the N-th writing into the memory cell.

14. The device according to claim 10, wherein
the controller manages the number of times N block by block, the block including the memory cell arrays and being an erase unit of the data written in each the memory cells.

15. The device according to claim 10, wherein
each the memory cells is capable of holding M-value data (≧four values) or two-value data which is “0” or “1” depending on the read level, and
the controller turns to a first method or a second method, the first method reading the data “0” or “1” from the memory cell according to the read level, the second method reading any one of the M-value data.

16. The device according to claim 11, wherein
when an m-th (m: a natural number equal to or more than 2) write request is issued to the memory cell,
the controller causes the voltage generator to generate the read voltage corresponding to an (m−1)th time, and uses this read voltage to read the “1” bit data from the memory cell, and
according to the data corresponding to the write request, the controller causes the voltage generator to generate the write voltage which changes to a threshold voltage higher than a threshold voltage at which the data is read in the (m−1)th reading.

17. The device according to claim 11, wherein
when an m-th (m: a natural number equal to or more than 2) write request is issued to the memory cell,
the controller causes the voltage generator to generate the read voltage corresponding to an (m−1)th time, and uses this read voltage to read the “1” bit data from the memory cell, and
when a threshold voltage of the memory cell is lower than the (m−1)th read voltage, the controller changes the threshold-voltage of the memory cell to a threshold voltage higher than the (m−1)th read voltage, and then performs the m-th writing into the memory cell.

18. The device according to claim 15, wherein
the controller manages the first method or the second method block by block, the block including the memory cell arrays and being an erase unit of the data written in each the memory cells.

19. The device according to claim 17, wherein
the memory cell is capable of changing to a state distribution of one of a first state, a second state, and a third state which are separated from one another in ascending order of threshold voltage,
the controller holds a maximum overwriting count which allows the data to be sequentially written into each the memory cells, and
the controller subtracts one from the maximum overwriting count according to a potential difference between an upper threshold voltage in the first state and a lower threshold voltage in the second state or in accordance with a potential difference between an upper threshold voltage in the second state and a lower threshold voltage in the third state.

20. The device according to claim 19, wherein
the voltage generator generates a first voltage and a second voltage as the write voltages, the first voltage changing the threshold voltage of each the memory cells from the first state to the second state, the second voltage changing the threshold voltage of each the memory cells from the first state or the second state to the third state and being higher than the first voltage,
the voltage generator generates a third voltage and a fourth voltage as the read voltages, the third voltage being higher than the upper threshold voltage in the first state and lower than the lower threshold voltage in the second state, the fourth voltage being higher than the upper threshold voltage in the second state and lower than the lower threshold voltage in the third state, and
when new writing data is transferred, the controller transfers the third voltage or the fourth voltage to each the memory cells according to the counted value and thereby reads the “1” bit data of “0” or “1” held in each the memory cells.
